(19) United States
(12) Patent Application Publication
(10) Pub. No.: US 2022/0052163 A1
(43) Pub. Date: Feb. 17, 2022

(54) GATE CONTROL FOR HEMT DEVICES USING DIELECTRIC BETWEEN GATE EDGES AND GATE FIELD PLATES

(71) Applicant: SEMICONDUCTOR COMPONENTS INDUSTRIES, LLC, Phoenix, AZ (US)

(72) Inventors: Peter COPPENS, Kanegem (BE); Aurore CONSTANT, Oudenaarde (BE); Piet VANMEERBEEK, Sleidinge (BE)

(73) Assignee: SEMICONDUCTOR COMPONENTS INDUSTRIES, LLC, Phoenix, AZ (US)

(21) Appl. No.: 16/948,804

(22) Filed: Oct. 1, 2020

Related U.S. Application Data
(60) Provisional application No. 62/706,403, filed on Aug. 14, 2020.

(51) Int. Cl. H01L 29/40; H01L 29/20; H01L 29/205; H01L 29/423; H01L 29/778; H01L 21/285; H01L 21/765; H01L 29/66

(52) U.S. Cl. CPC H01L 29/404; H01L 29/2003; H01L 29/205; H01L 29/66462; H01L 29/7786; H01L 21/28587; H01L 21/765; H01L 29/42316

(57) ABSTRACT

In a high electron mobility transistor (HEMT), dielectric material may be included between edge portions of a HEMT gate and gate field plates in contact with a HEMT gate electrode. At least some portions of the HEMT gate and HEMT gate electrode remain in direct contact with one another, and the HEMT gate electrode and gate field plates may be further connected to a gate metal.

### CROSS-REFERENCE TO RELATED APPLICATIONS

This application claims the benefit of U.S. Provisional Patent Application No. 62/706,403, filed on Aug. 14, 2020, the entire contents of which is incorporated herein by reference.

### TECHNICAL FIELD

This description relates to High Electron Mobility Transistors (HEMTs).

### BACKGROUND

A HEMT is a type of transistor that utilizes a current channel formed using a heterojunction at a boundary between two materials having different band gaps. For example, a relatively wide band gap material such as AlGaN (Aluminum Gallium Nitride) may be doped with n-type impurities and used to form a junction with an undoped, relatively narrow band gap material, such as GaN (Gallium Nitride). Then, an equilibrium is reached in which the narrow band gap material has excess majority carriers that form a 2-dimensional electron gas (2DEG). Consequently, and because the narrow band gap material has no doping impurities to disrupt current flow through scattering, HEMT devices provide, among other advantages, very high switching speeds, high gains, and high power applications.

### SUMMARY

According to one general aspect a High Electron Mobility Transistor (HEMT) includes a source, a drain, a channel layer extending between the source and the drain, and a barrier layer formed in contact with the channel layer, and extending between the source and the drain. The HEMT includes a gate formed in contact with, and covering at least a portion of, the barrier layer, the gate having a first gate edge portion, a second gate edge portion, and a gate central portion, and a gate electrode contacting the gate central portion. The HEMT includes a first gate field plate contacting a first side of the gate electrode, and a second gate field plate contacting a second side of the gate electrode, and further includes a first dielectric layer formed between the first gate edge portion and the first gate field plate, and a second dielectric layer formed between the second gate edge portion and the second gate field plate.

According to another general aspect, a gate structure for a High Electron Mobility Transistor (HEMT) device may include a gate formed in contact with, and covering a portion of, a barrier layer of the HEMT, the gate having a first gate edge portion, a second gate edge portion, and a gate central portion. The gate structure may include a gate electrode formed in contact with the gate central portion. The gate structure may include a first gate field plate contacting a first side of the gate electrode, and a second gate field plate contacting a second side of the gate electrode, and may further include a first dielectric layer formed between the first gate edge portion and the first gate field plate, and a second dielectric layer formed between the second gate edge portion and the second gate field plate.

According to another general aspect, a method of making a High Electron Mobility Transistor (HEMT) includes forming a layer stack that includes at least a channel layer and a barrier layer adjacent to the channel layer and forming a heterojunction at which a current channel is defined in the channel layer, and forming a gate having a first gate edge portion, a second gate edge portion, and a gate central portion. The method further includes forming a gate electrode contacting the gate central portion. The method further includes forming a first gate field plate contacting a first side of the gate electrode, and forming a second gate field plate contacting a second side of the gate electrode. The method further includes forming a first dielectric layer between the first gate edge portion and the first gate field plate, and forming a second dielectric layer between the second gate edge portion and the second gate field plate.

The details of one or more implementations are set forth in the accompanying drawings and the description below. Other features will be apparent from the description and drawings, and from the claims.

### BRIEF DESCRIPTION OF THE DRAWINGS

FIG. 1 illustrates a cross-section of a HEMT with dielectric between gate edges and gate field plates.

FIG. 2 illustrates an electric field and associated depletion layer of the embodiment of FIG. 1, during a gate bias.

FIG. 3 illustrates a cross-section of an alternate embodiment of the embodiment of FIG. 1.

FIG. 4 illustrates a cross-section of another alternate embodiment of the embodiment of FIG. 1.

FIG. 5 is a flowchart illustrating example operations for forming a HEMT in accordance with the example embodiments of FIGS. 1-4.

FIG. 6 illustrates a cross-section of a first example operation of a first process for forming a HEMT with dielectric between gate edges and gate field plates.

FIG. 7 illustrates a cross-section of a second example operation of a first process for forming a HEMT with dielectric between gate edges and gate field plates.

FIG. 8 illustrates a cross-section of a third example operation of a first process for forming a HEMT with dielectric between gate edges and gate field plates.

FIG. 9 illustrates a cross-section of a fourth example operation of a first process for forming a HEMT with dielectric between gate edges and gate field plates.

FIG. 10 illustrates a cross-section of a fifth example operation of a first process for forming a HEMT with dielectric between gate edges and gate field plates.

FIG. 11 illustrates a cross-section of a sixth example operation of a first process for forming a HEMT with dielectric between gate edges and gate field plates.

FIG. 12 illustrates a cross-section of a first example operation of a second process for forming a HEMT with dielectric between gate edges and gate field plates.

FIG. 13 illustrates a cross-section of a second example operation of a second process for forming a HEMT with dielectric between gate edges and gate field plates.

FIG. 14 illustrates a cross-section of a third example operation of a second process for forming a HEMT with dielectric between gate edges and gate field plates.

FIG. 15 illustrates a cross-section of a fourth example operation of a second process for forming a HEMT with dielectric between gate edges and gate field plates.

FIG. 16 illustrates a cross-section of a fifth example operation of a second process for forming a HEMT with dielectric between gate edges and gate field plates.

FIG. 17 illustrates a cross-section of a first example operation of a third process for forming a HEMT with dielectric between gate edges and gate field plates.

FIG. 18 illustrates a cross-section of a second example operation of a third process for forming a HEMT with dielectric between gate edges and gate field plates.

FIG. 19 illustrates a cross-section of a third example operation of a third process for forming a HEMT with dielectric between gate edges and gate field plates.

FIG. 20 illustrates a cross-section of a fourth example operation of a third process for forming a HEMT with dielectric between gate edges and gate field plates.

FIG. 21 illustrates a cross-section of a fifth example operation of a third process for forming a HEMT with dielectric between gate edges and gate field plates.

FIG. 22 illustrates a side angle view of a first example embodiment of a gate metal and gate electrode for a HEMT with dielectric between gate edges and gate field plates.

FIG. 23 illustrates a side angle view of a second example embodiment of a gate metal and gate electrode for a HEMT with dielectric between gate edges and gate field plates.

FIG. 24 illustrates a side angle view of a third example embodiment of a gate metal and gate electrode for a HEMT with dielectric between gate edges and gate field plates.

FIG. 25 illustrates example current/voltage graphs for described embodiments.

FIG. 26 illustrates additional example current/voltage graphs for described embodiments.

### DETAILED DESCRIPTION

As described in detail below, embodiments include a HEMT in which dielectric material is included between edge portions of a HEMT gate and gate field plates for the HEMT gate that are in contact with a HEMT gate electrode for the HEMT gate. At least some portions of the HEMT gate and HEMT gate electrode remain in direct contact with one another, and the HEMT gate electrode may be further connected to a gate metal.

Such embodiments provide a high degree of HEMT gate control, including a low gate turn-on voltage, and a more uniform gate control that extends to the edges of the HEMT gate. In particular, the described embodiments provide improvements in uniformity of gate control due to corresponding improvements in uniformity of an electric field (and associated depletion layer) across a surface of the HEMT gate that is in contact with the HEMT gate electrode.

Further, the described embodiments advantageously combine the above-referenced gate control with high gate breakdown voltages. For example, due to the electric field uniformity just referenced, electric field peaks at edges of the HEMT gate are avoided or minimized, which results in increases in tolerable gate voltages before gate breakdown is reached. As a result, the described embodiments provide fast switching with high reliability, even for high power applications.

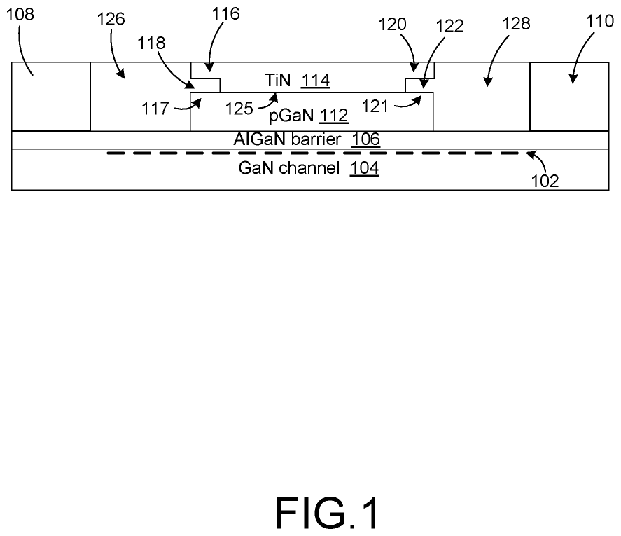

FIG. 1 illustrates a cross-section of a HEMT with dielectric between gate edges and gate field plates. In FIG. 1, a channel layer 104 is formed in contact with a barrier layer 106, and forms a heterojunction with the barrier layer 106. The heterojunction occurring at the interface of the channel layer 104 and the barrier layer 106 causes a channel region 102 that includes a 2DEG region of high electron mobility. For example, the channel layer 104 may be an undoped material with a relatively large width and relatively narrow bandgap energy (such as, e.g., Gallium Nitride, or GaN), while the barrier layer 106 may be a doped material with a relatively thin width and a relatively wide bandgap energy (such as, e.g., Aluminum Gallium Nitride, or AlGaN).

Further in FIG. 1, a source 108 is illustrated that refers generally to a source contact and source region of the HEMT, while a drain 110 similarly refers to a drain contact and drain region of the HEMT. During operation of the HEMT, current flows between the source 108 and the drain 110, by way of the channel region 102.

In general, due to the presence of the 2DEG referenced above, it is straightforward to form a ‘normally-on’ or depletion mode HEMT, in which source/drain current flows as a default state of the device. However, particularly for high power applications, a ‘normally-off’ or enhancement mode HEMT may be desired, in which the source/drain current is prohibited as a default state. In general, normally-off HEMTs may have an improved safety profile in high power applications, and may simplify related drive circuitry.

In FIG. 1, the HEMT is maintained in a normally-off state through the use of a gate 112. That is, the HEMT of FIG. 1 may represent a normally-off device that prevents current flow through the channel region 102, unless the gate 112 is activated/biased.

For example, the gate 112 may be implemented as a p-type layer of GaN, also referred to as pGaN, which is at least partially covering the barrier layer 106. For example, the pGaN layer 112 may be doped with Magnesium. The pGaN layer 112, barrier layer 106, and channel layer 104 may be understood to form a PIN (p-type, intrinsic, n-type) diode structure with a depletion zone that extends over the channel layer 104. This depletion zone disrupts the 2DEG of the channel region 102 in a default or unbiased state (e.g., V_{gs}=0V), but is rapidly removed by application of a positive bias at the gate 112, which thereby allows source-drain current to flow.

Use of the gate 112 establishes a turn-on voltage for the HEMT of FIG. 1. As with many gate structures, the gate 112 may be susceptible to various failure mechanisms, such as gate breakdown and/or leakage currents, which may occur in response to undesirably high gate voltages. The HEMT of FIG. 1 provides low turn-on voltages, while also increasing gate breakdown voltages. Consequently, the HEMT of FIG. 1 provides fast switching speeds and high reliability, even for high power applications.

For example, in the example embodiment of FIG. 1, a gate electrode 114 is illustrated, which may be used in applying a positive bias to the gate 112, as just referenced, and as described in further detail, below. As illustrated, the gate electrode 114 is in contact with a first gate field plate 116 that is parallel to a first gate edge portion 117 of the gate 112. A first dielectric layer 118 is between the first gate field plate 116 and the first gate edge portion 117. Similarly, the gate electrode 114 includes a second gate field plate 120 that is parallel to a second gate edge portion 121 of the gate 112. A second dielectric layer 122 is between the second gate field plate 120 and the second gate edge portion 121. As also illustrated, the gate electrode 114 is in contact with a gate central portion 125 of the gate 112.

In FIG. 1, the first dielectric layer 118 may be formed in conjunction with dielectric 126, which provides separation and passivation with respect to the source contact 108 and the barrier layer 106. Similar comments apply to second dielectric layer 128, with respect to the dielectric layer 122, drain 110, and barrier layer 106.

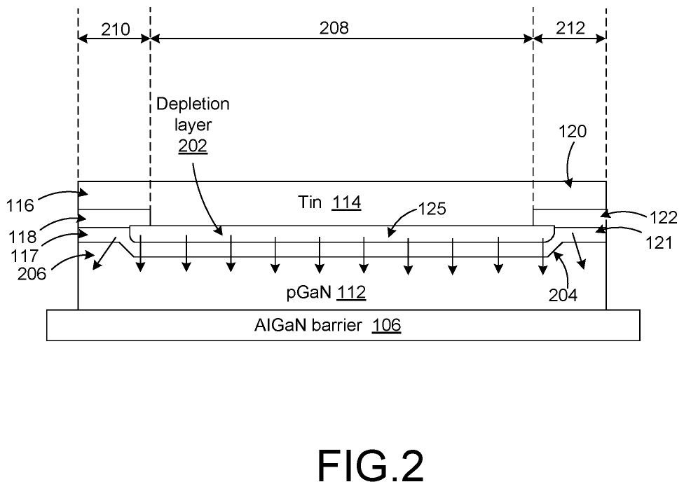

FIG. 2 illustrates an electric field 204 and associated depletion layer 202 of the embodiment of FIG. 1, during a gate bias. As may be observed by arrows 206 in FIG. 2, the electric field 204 provides a uniform hole supply within the depletion layer 202, while reducing electric field crowding (electric field peaks) that might otherwise occur at edges of the electric field, by extending the electric field 204 through edge portions 117, 121 of the gate 112.

As referenced with respect to FIG. 1, the low electrical field peak at the gate edge portions 117, 121 of the gate 112 results in improved gate breakdown characteristics. This result is achieved by the inclusion of the dielectric layers 118, 122, between the gate edge portions 117, 121 and the gate field plates 116, 120, as shown, to avoid electric field peaks within the gate edge portions 117, 121.

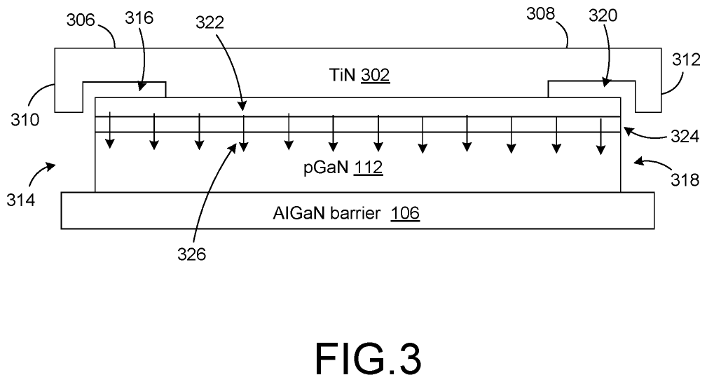

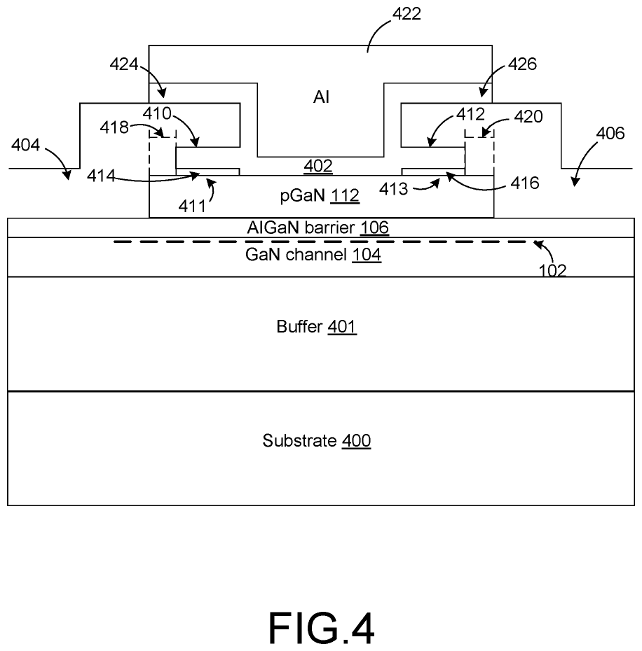

The gate electrode 114 may have a width illustrated in FIG. 2 as 208, while the first gate field plate 116 is illustrated as having a width 210, and the second gate field plate 120 is illustrated as having a width 212. As illustrated in example embodiments of FIGS. 3 and 4, widths 208, 210, 212 may be varied relative to one another, and/or relative to a width of the underlying gate 112, to achieve various effects and optimizations.

For example, in FIG. 3, an example gate electrode 302 is illustrated as being in contact with a first gate field plate 306, and a second gate field plate 308. As may be observed, the gate field plates 306, 308 extend past gate edge portions of the gate 112, which enables inclusion of a first substantially perpendicular gate field plate 310 and a second substantially perpendicular gate field plate 312.

As shown, the perpendicular gate field plates 310, 312 extend in a direction perpendicular to a surface of the gate 112, or of the gate electrode 302, and in a direction of the barrier layer 106. Dielectric 314 and dielectric 316 extend between, and separate, the gate field plates 306, 310 and the gate 112. Similar comments apply to dielectric 318 and dielectric 320, which extend between, and separate, the gate field plates 308, 312 and the gate 112.

As a result, and as illustrated in FIG. 3, arrows 326 show a further improvement in a uniformity of the depletion layer 322 and associated electric field 324. This uniform electrical field build-up in the gate 112 provides a correspondingly uniform hole supply across an entirety of the gate 112, and uniform HEMT current flow during HEMT activation.

FIG. 4 illustrates a cross-section of another alternate embodiment of the embodiment of FIG. 1. FIG. 4 illustrates a substrate 400, which may be, e.g., GaN, Si, Silicon Carbide (SiC), Aluminum Nitride (AlN), or Sapphire (e.g., monocrystalline Al₂O₃). Also in FIG. 4, a buffer layer 401 is illustrated that may be advantageous in scenarios in which the device of FIG. 4 is used in high voltage contexts. For example, the buffer layer 401 may include carbon-doped Gallium Nitride (GaN). By doping the GaN buffer layer 401 with Carbon or other suitable p-type material, the n-type nature of GaN is effectively counter-doped, so that the buffer layer 401 is more insulative and able to sustain high V.

Although not separately illustrated within FIG. 4, a strain relief layer may be included, if needed to facilitate strain relief with respect to any lattice mismatch that may occur. For example, if the buffer layer 401 is not used, a strain relief layer might be included between the substrate 400 and the channel layer 104. For example, a GaN channel layer has a non-trivial lattice mismatch with a substrate 400 formed of Si. The resulting strain at the junction may be relieved, for example, by including GaN doped with a percentage of Al within an intervening strain relief layer.

Further in FIG. 4, a gate electrode 402 is illustrated as being insulated by a dielectric 404 and a dielectric 406. The gate electrode 402 is in contact with a first gate field plate 410, and a second gate field plate 412. A dielectric layer 414 is illustrated as being included between the first gate field plate 410 and a first gate edge portion 411, while a dielectric layer 416 is illustrated as being included between the second gate field plate 412 and a second gate edge portion 413.

In FIG. 4, the first gate field plate 410 is recessed from an edge of the gate 112 by a distance 418. Similarly, the second gate field plate 412 is recessed from an edge of the gate 112 by a distance 420. Put another way, the lengths 210, 212 of FIG. 2 are reduced in the implementation of FIG. 4.

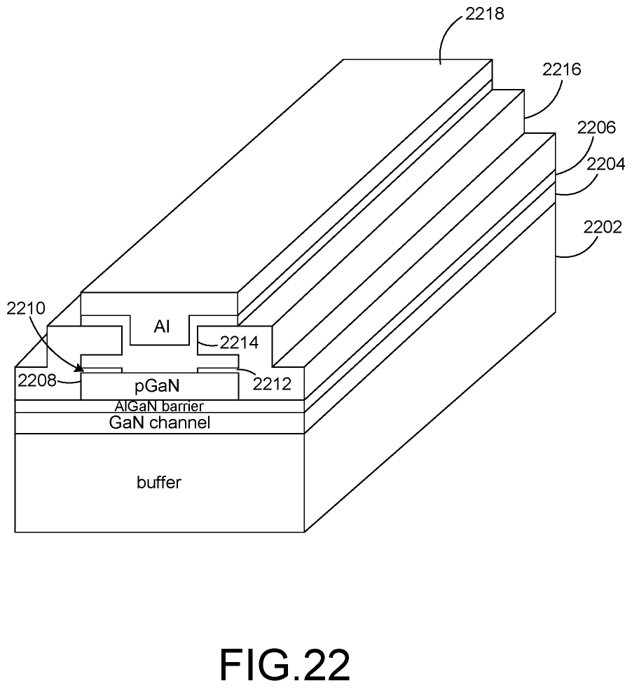

Also in FIG. 4, the gate electrode 402 is illustrated as being in contact with third gate field plate 424 and fourth gate field plate 426, which are illustrated as extending between and over the dielectrics 404, 406 The gate electrode 402, third gate field plate 424, and the fourth gate field plate 426 are in electrical contact with a gate metal 422, such as an Al gate metal. The gate metal 422 enables electrical contact to other devices, as further described and illustrated below, e.g., with respect to FIGS. 22-24. Then, as the gate electrode 402 is between the gate 112 and the gate metal 422, the gate electrode 402 may be referred to as a gate interlayer.

Dielectric layers included between gate edges and gate field plates as described herein may have thicknesses of less than about 6 nm, e.g., between about, e.g., 2-6 nm. A design of the gate electrode may depend in part on a chosen thickness of the dielectric layers.

For example, for relatively thinner dielectric layers, such as, e.g., 2-3 nm, a gate breakdown voltage may reach undesirably low levels. In such cases, as in FIG. 4, a lateral recess of the first and second gate field plates 410, 412 (e.g., recess distances 418, 420 of about 100 nm) may be desirable to maintain an acceptable breakdown voltage, while still obtaining a low turn-on voltage.

For relatively thicker dielectric layers, e.g., 5-6 nm, gate breakdown voltage may be sufficiently high, and it may be desirable to extend gate control to the gate ends by extending a length of the gate field plates, as shown in FIGS. 1-3.

In the embodiments of FIGS. 1-4, inclusion of dielectric between HEMT gate edges and HEMT gate field plates enables a capacitive coupling between the HEMT gate and HEMT gate field plates, when a gate bias voltage is applied. In addition to the favorable turn-on and breakdown characteristics referenced above, such capacitive coupling provides a high degree of gate control over a full width of the gate 112. Gate leakage that may occur through the metal electrode (e.g., 114, 302, 402), but may be tailored and optimized by selection of a width of contact thereof to the underlying gate 112. Put another way, a size of capacitor(s) formed by the capacitive coupling referenced above may be controlled by adjusting a relative size of agate electrode (e.g., 114 of FIG. 1, or 408 of FIG. 4), and associated gate field plates.

Thus, FIGS. 1-4 illustrate that a HEMT gate may be understood to have a gate length, equivalent to the full lengths 208, 210, 212 of FIG. 2, that extends from a first end of a first gate edge portion to a second end of a second gate edge portion. Relative to this gate length, a first gate field plate may extend from agate electrode to at least the first end (as shown in FIGS. 1 and 2), or past the first end (as shown in FIG. 3, in which case perpendicular field plates may be included as well, as described with respect to FIG. 3), or may be recessed from the first end (as shown in FIG. 4). Similarly, the second gate field plate may extend from the gate electrode to at least the second end, beyond the second end, or may be recessed from the second end.

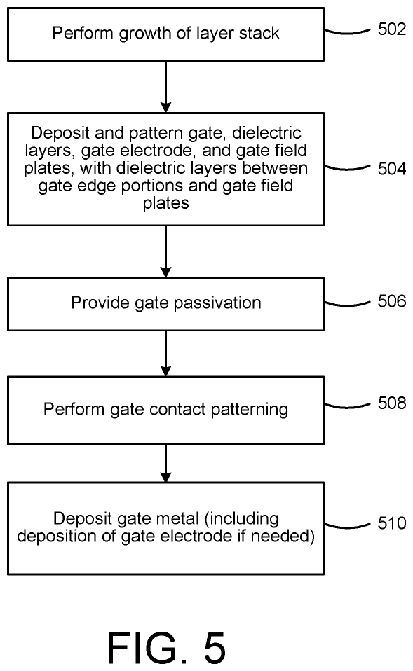

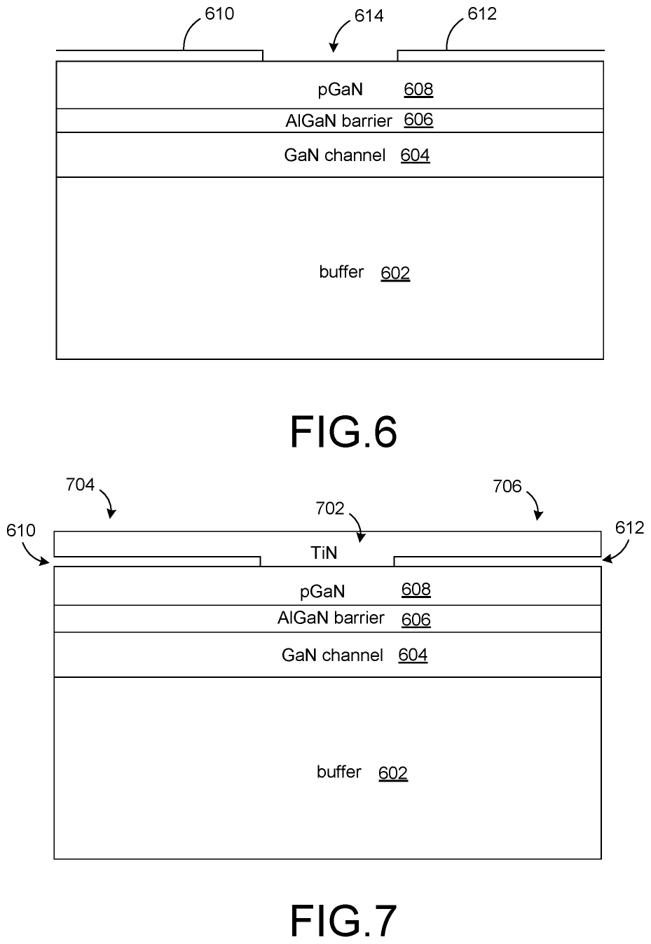

FIG. 5 is a flowchart illustrating example operations for forming a HEMT in accordance with the example embodiments of FIGS. 1-4. Although operations 502-510 are illustrated as separate, sequential operations, the various operations may be performed in a different order than that shown, and/or may include various sub-operations. Several example implementations of the processes of FIG. 5 are illustrated and described below, with respect to FIGS. 6-11, 12-16, and 17-21.

In FIG. 5, a layer stack for a HEMT may be formed (502). For example, a layer stack including a substrate, buffer, strain relief layer, channel layer, barrier layer, and gate layer may be formed. Examples of layer stacks formed are provided below, e.g., with respect to FIGS. 6, 12, and 17.

A gate, dielectric layers, gate electrode, and gate field plates, with dielectric layers between gate field plates and gate edge portions, may be deposited and patterned (504). Many different techniques may be used to deposit the gate, dielectric layers, gate electrode, and gate field plates to obtain the structures of FIGS. 1-4, and other variations thereof. For example, the gate and gate field plates may be formed in a self-aligned manner. In some implementations, as described below, the gate field plates, gate edge portions, and intervening dielectric layers may be formed together, while gate electrode may be formed during later stages of device formation. Various example implementations are illustrated and described below, e.g., with respect to FIGS. 6-8, 13-16, and 18-21.

Gate passivation may be provided (e.g., performed, formed) (506), including depositing of suitable dielectric material over/around the gate, gate electrode, and gate field plates, as well as over a barrier layer underlying the gate. Examples of gate passivation are illustrated and described with respect to 9-11, 14-16, and 18-21.

Gate contact patterning may be performed (508). That is, patterning may be conducted to enable inclusion of gate metal layers to connect the HEMT being constructed to other HEMT devices, or other devices in general.

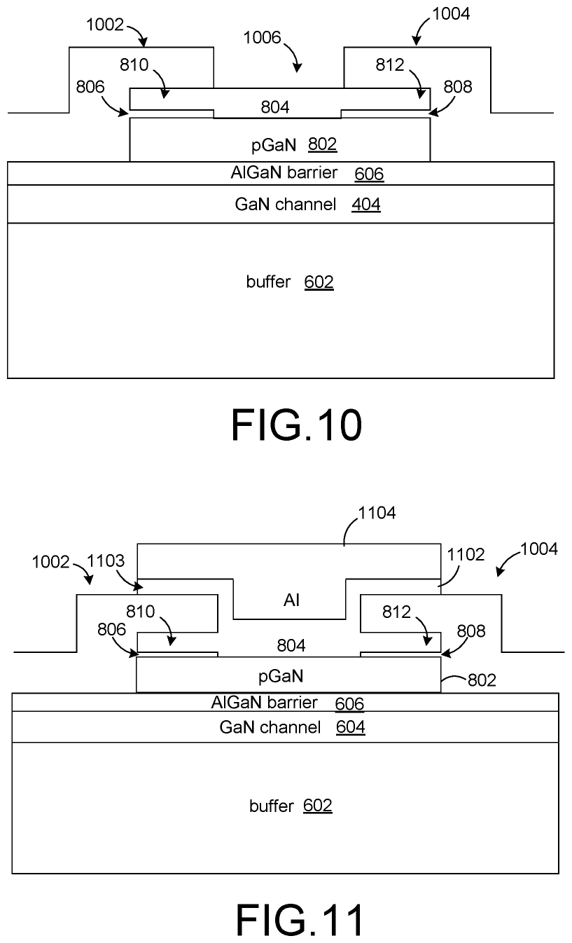

Finally in FIG. 5, a gate metal may be deposited (510). Examples are illustrated with respect to FIGS. 11, 16, and 21. In some implementations, such as FIGS. 10, 11, the gate electrode will have already been formed. In other implementations, such as FIGS. 15, 16, and FIGS. 20, 21, the gate electrode may be deposited in conjunction with the gate metal deposition.

FIGS. 6-11 illustrate cross-sections of example operations of a first process for making a HEMT with dielectric between gate edges and gate field plates.

In FIG. 6, a layer stack is formed that includes a buffer layer 602, channel layer 604, barrier layer 606, and gate layer 608. Also in FIG. 6, a thin dielectric layer may be deposited and patterned to form dielectric layers 610, 612, with opening 614 formed therebetween. For example, the dielectric layers 610, 612 may be formed as SiO₂, or Al₂O₃, Si₃N₄, or other suitable dielectric. In some implementations, the dielectric layers 610, 612 may be sufficiently thin to result in the capacitive coupling described herein between gate edges and gate field plates, in a range of, e.g., 2-6 nm.

In FIG. 7, gate electrode material, such as Titanium Nitride (TiN) 702, is deposited, filling the opening 614 and thereby contacting the gate layer 608. Gate field plates 704, 706 (which may also be formed using TiN, are formed covering the dielectric layers 610, 612, as shown.

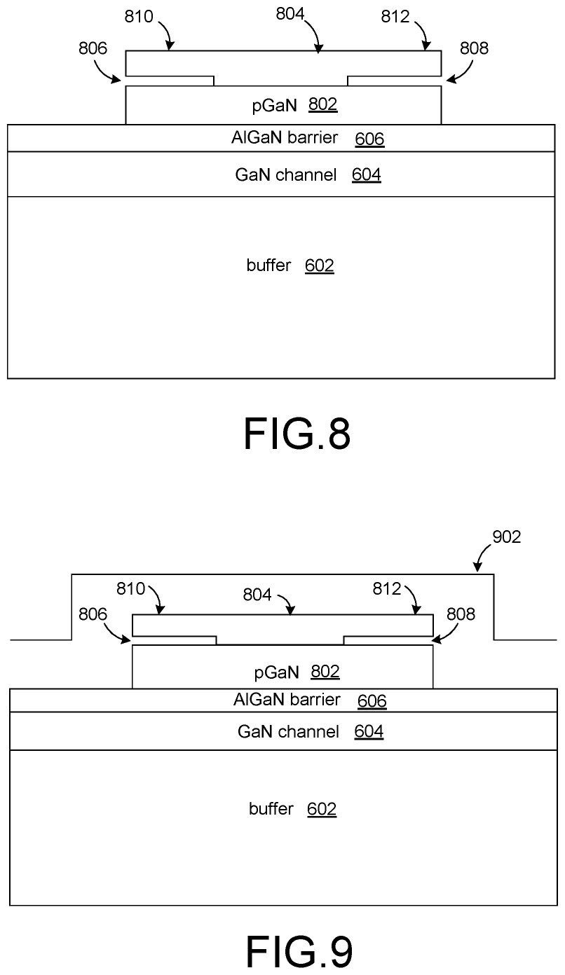

In FIG. 8, a gate 802, gate electrode 804, dielectric layers 806, 808, and gate field plates 810, 812 are thus formed in a self-aligned manner as part of gate patterning operations. As shown, the result is a gate structure similar to that of FIG. 1.

In FIG. 9, dielectric layer 902 is formed over an entirety of the structure, to provide gate passivation. In FIG. 10, gate contact patterning proceeds with etching of an opening 1006 to define separate dielectric regions 1002, 1004.

Then, in FIG. 11, additional gate field plates 1102, 1103 are added, followed by deposition of gate metal 1104. In some implementations, the gate metal 1104 may be deposited directly on gate electrode 804, and gate field plates 1102, 1103.

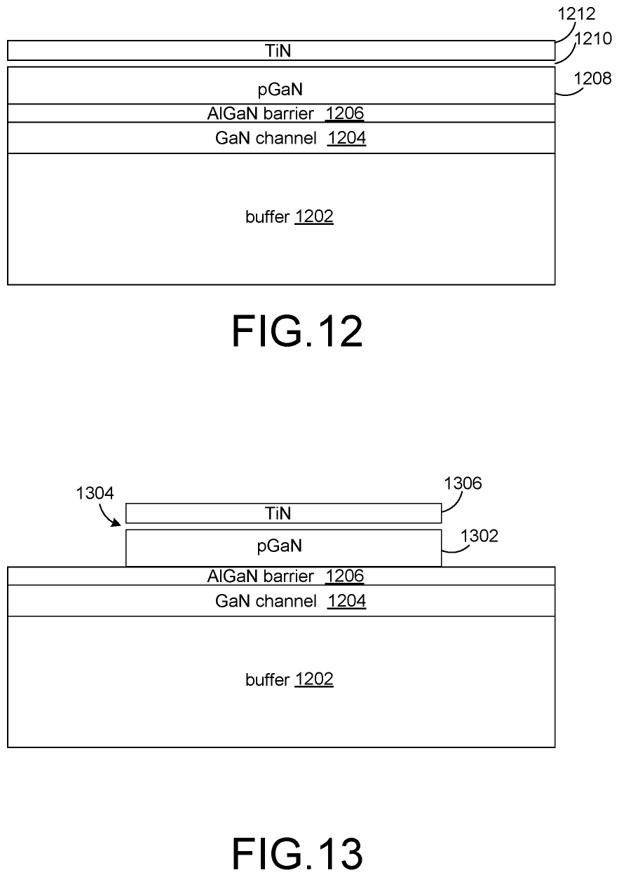

FIGS. 12-16 illustrate cross-sections of example operations of a second process for forming a HEMT with dielectric between gate edges and gate field plates.

In FIG. 12, a layer stack is formed that includes a buffer layer 1202, channel layer 1204, barrier layer 1206, and gate layer 1208. A dielectric layer 1210 and gate field plate layer 1212 are also formed.

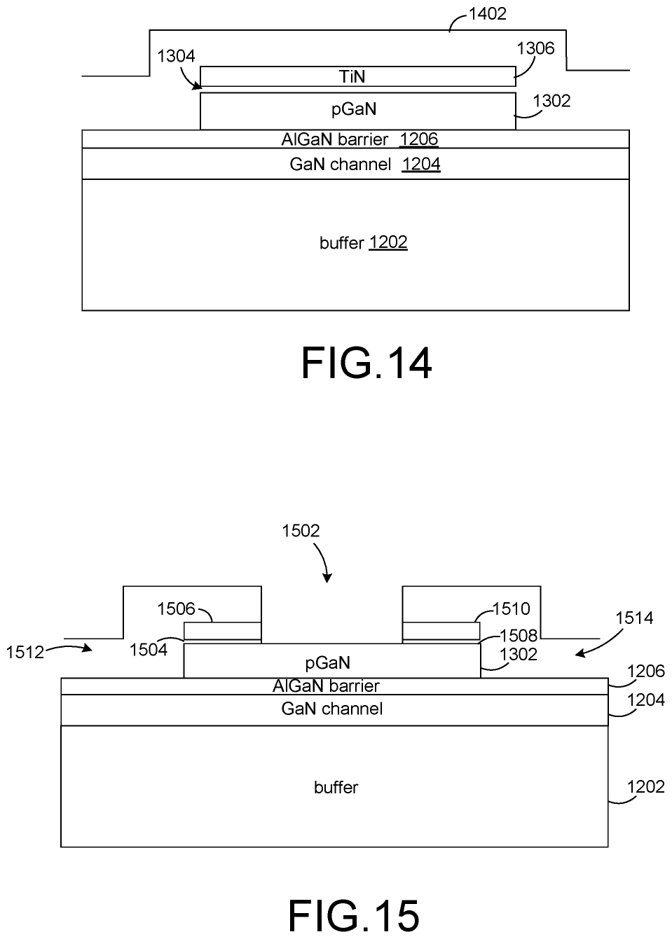

In FIG. 13, gate 1302, dielectric layer 1304, and gate field plate layer 1306 are formed in a self-aligned manner. In FIG. 14, a passivation dielectric 1402 is added around the gate structure 1302, 1304, 1306.

In FIG. 15, gate contact patterning proceeds with etching an opening 1502 through the layers 1402, 1304, 1306 to reach the gate 1302. Accordingly, dielectric layer 1504 is formed between the gate 1302 and a first gate field plate 1506, while dielectric layer 1508 is formed between the gate 1302 and a second gate field plate 1510. Meanwhile, passivation layer 1402 is separated into dielectric portions 1512, 1514.

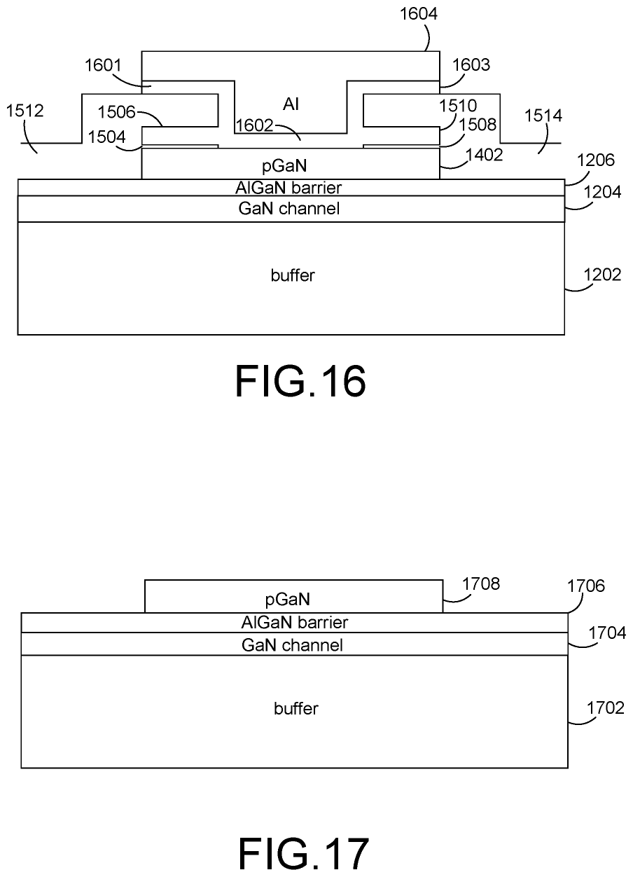

In FIG. 16, gate electrode layer 1602 is added, including gate field plates 1601, 1603. Gate metal 1604 may then be added.

FIGS. 17-21 illustrate cross-sections of example operations of a third process for forming a HEMT with dielectric between gate edges and gate field plates.

In FIG. 17, a layer stack is formed that includes a buffer layer 1702, channel layer 1704, and barrier layer 1706. In FIG. 17, gate 1708 has already been formed from a preceding gate layer.

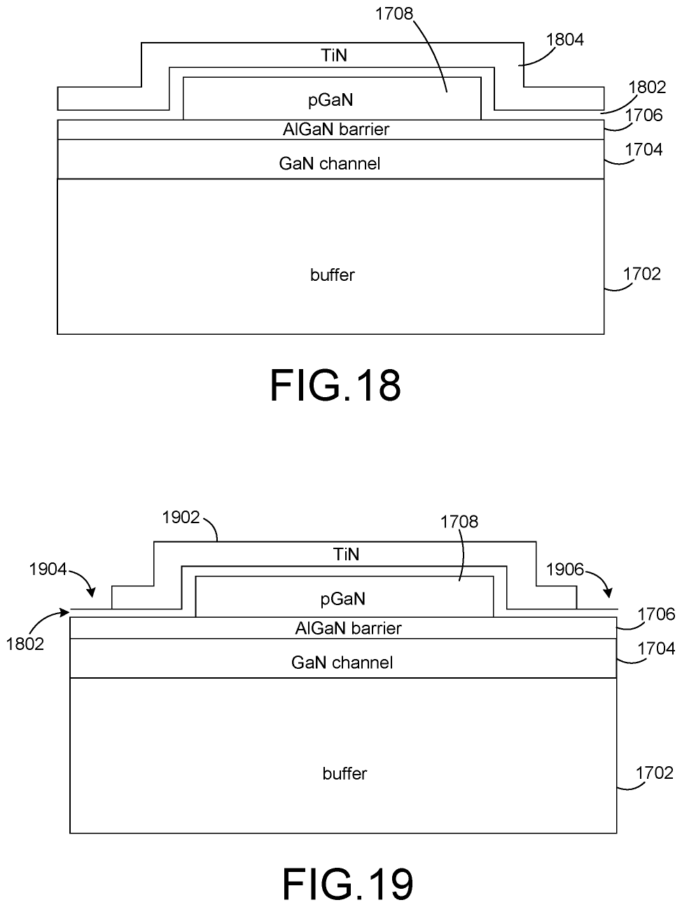

In FIG. 18, dielectric layer 1802 is formed over the barrier layer 1706 and the gate 1708. Then, gate field plate layer 1804 is formed over the dielectric layer 1802.

In FIG. 19, gate field plate patterning is illustrated. As shown, portions of the gate field plate layer 1804 are removed to leave a gate field plate layer 1902 and provide openings 1904, 1906 above the dielectric layer 1802 and over the barrier layer 1706.

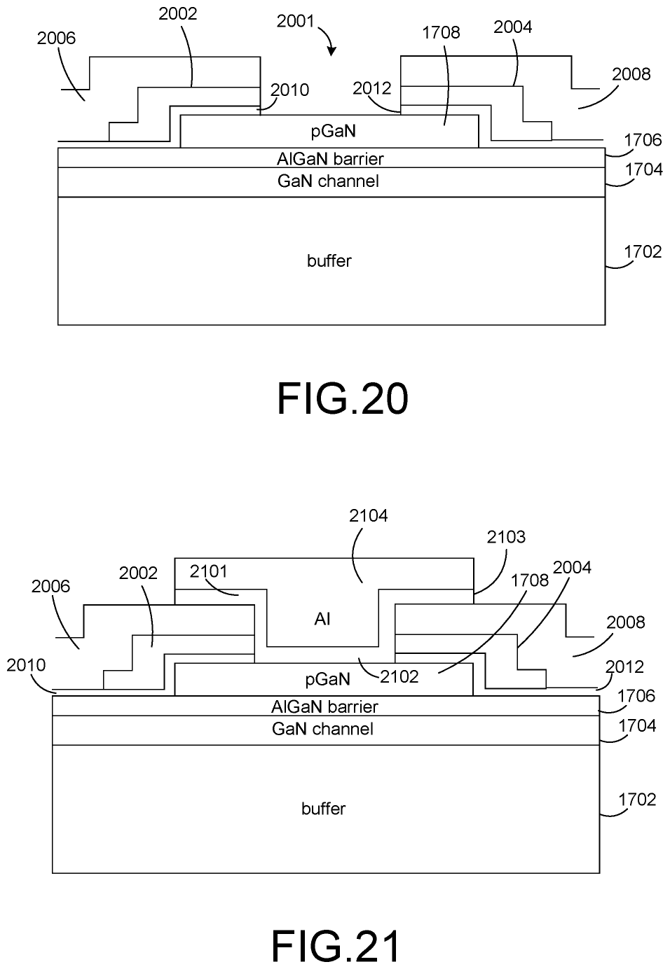

Following deposition of a passivation dielectric, gate contact patterning proceeds in FIG. 20 with etching an opening 2001 to obtain dielectric portions 2006, 2008, gate field plates 2002, 2004, and dielectric portions 2010, 2012. In FIG. 21, deposition of gate electrode 2102 may occur, along with additional gate field plates 2101, 2103. Gate metal 2104 may then be deposited.

FIGS. 22-24 illustrate side angle views of example embodiments of a gate metal and gate electrode for a HEMT with dielectric between gate edges and gate field plates. Each of FIGS. 22-24 illustrate different approaches to forming gate and gate metal connections.

Specifically, in FIG. 22, a buffer layer 2202, channel layer 2204, and barrier layer 2206 are illustrated, along with gate 2208. In FIG. 22, a gate electrode and associated gate field plates as described above are referenced singularly as gate electrode/field plate structure 2214. Dielectric layers 2210, 2212 are formed between edges of the gate 2208 and the gate electrode/field plate structure 2214. Passivation dielectric 2216 and gate metal 2218 are also illustrated.

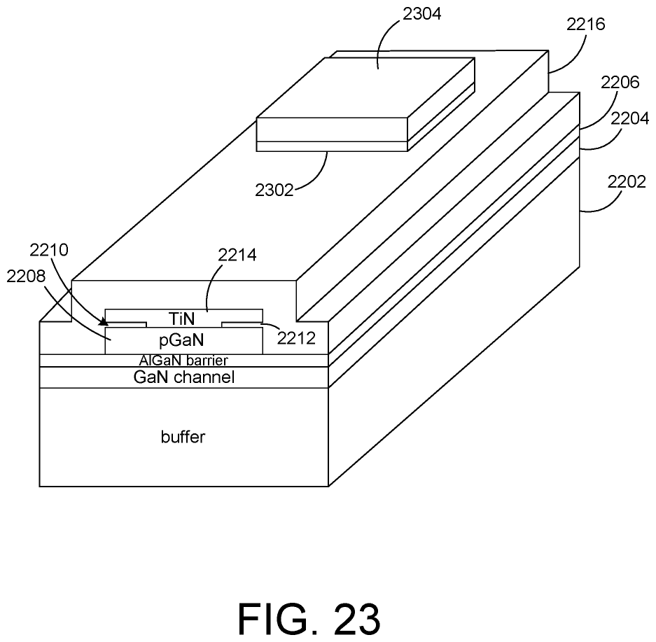

In FIG. 22, the gate 2208, gate electrode/field plate structure 2214, and gate metal 2218 illustrate a full gate connection throughout a length of the structure of FIG. 22. In contrast, in FIG. 23, a full gate connection of the gate 2208 is shown with a local connection 2302 of gate electrode/field plate structure 2214 and gate metal 2304.

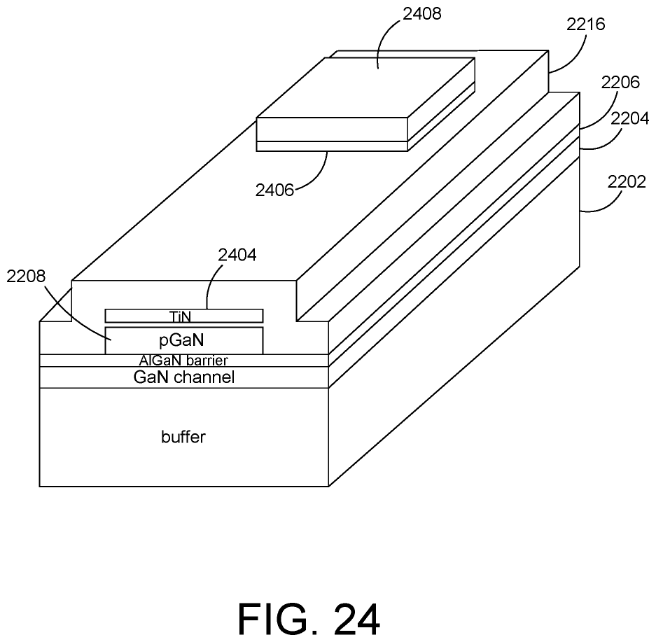

In the final example of FIG. 24, connection to the gate 2208 is localized, along with local connection 2406 of gate electrode/field plate structure 2404 and gate metal 2408. In other words, in FIG. 24, the gate structure(s) described above, in which dielectric layers are formed between gate edges and gate field plates, occurs only within the structure of FIG. 24 underneath the gate metal 2408, and is not visible in the example of FIG. 24.

In the examples of FIGS. 23 and 24, gate metals 2304/2408 are localized and therefore may be advantageous when implementing dense layout rules. For example, the implementations of FIGS. 23 and 24 enable inclusion of gate fingers that are perpendicular to the gate 2208.

Thus, FIGS. 22-24 illustrate a gate metal in electrical contact with the gate electrode, with a gate extending in a perpendicular direction that is substantially perpendicular to a line through the first gate edge portion, the second gate edge portion, and the gate central portion. The gate metal and the gate electrode extend in electrical contact with one another and with the gate along at least a portion of the gate in the perpendicular direction (as shown in FIGS. 22-24). The gate metal and gate electrode may extend fully along the perpendicular direction in electrical contact with the gate (as shown in FIG. 22), or the gate metal may extend only partially along the perpendicular direction while the gate electrode extends fully in electrical contact (as shown in FIG. 23), or both the gate metal and the gate electrode may extend only partially along the perpendicular direction in electrical contact with the gate (as shown in FIG. 24). In the cases of FIGS. 23, 24, a passivation dielectric may be formed over the gate electrode in the perpendicular direction when the gate metal extends in electrical contact with the gate electrode and with the gate over only the portion of the gate in the perpendicular direction. Put another way, the passivation dielectric may be formed around the gate and the gate electrode, wherein the gate electrode extends through a portion of the passivation dielectric and the gate metal is formed on the gate electrode. In this way, the gate metal may be formed on the gate electrode and provide a desired degree of electrical contact to the HEMT.

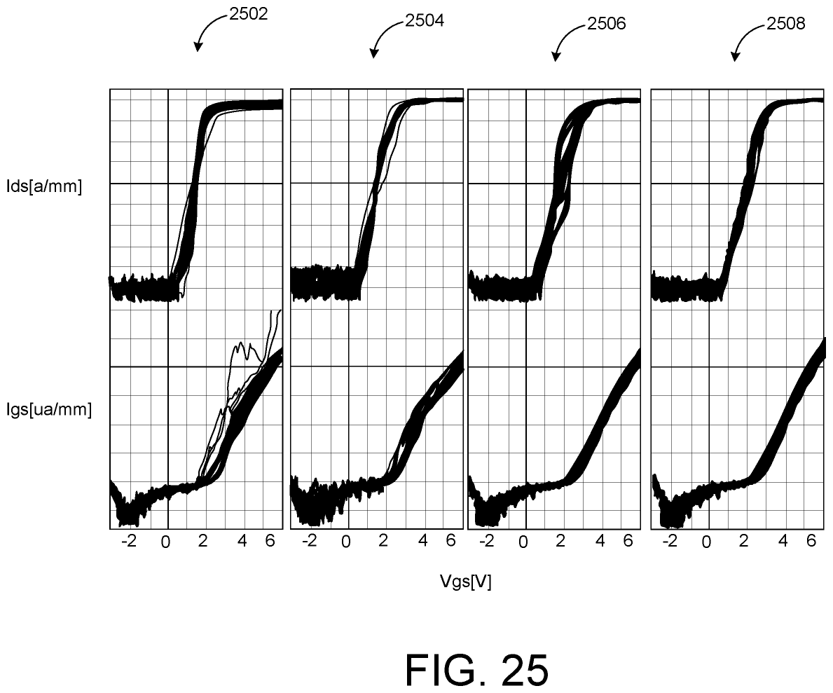

FIG. 25 illustrates example current/voltage graphs (2502, 2504, 2506 2508) for described embodiments. Specifically, graphs 2502 and 2506 correspond to examples of FIG. 1, while graphs 2504 and 2508 correspond to examples of FIG. 4. The graphs 2502 and 2504 illustrate examples with relatively thin dielectric layers 118/122 and 414/416, respectively, while graphs 2506 and 2508 illustrate examples with relatively thick dielectric layers 118/122 and 414/416, respectively (where relative thicknesses occur within the example ranges provided herein).

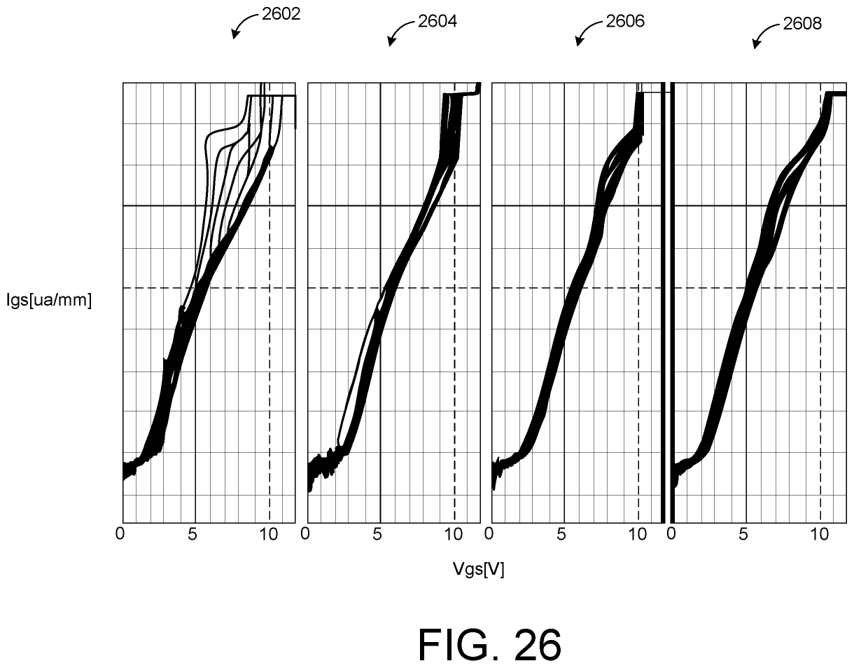

FIG. 26 illustrates additional example current/voltage graphs (2602, 2604, 2606, 2608) for described embodiments. Similar to FIG. 25, in FIG. 26, graphs 2602 and 2606 correspond to examples of FIG. 1, while graphs 2604 and 2608 correspond to examples of FIG. 4. The graphs 2602 and 2604 illustrate examples with relatively thin dielectric layers 118/122 and 414/416, respectively, while graphs 2606 and 2608 illustrate examples with relatively thick dielectric layers 118/122 and 414/416, respectively (where relative thicknesses occur within the example ranges provided herein).

FIG. 25 generally illustrates that a gate current I_{g} turns on at desirably low levels of threshold voltage Vth, while a drain-source current (I_{ds}) relative to a gate-source voltage (V_{gs}) has a desirably steep curve, indicating high transconductance. FIG. 26 illustrates that gate breakdown thresholds may be adjusted to desirable levels, using the techniques described herein.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A High Electron Mobility Transistor (HEMT), comprising:
a source;
a drain;
a channel layer extending between the source and the drain;
a barrier layer formed in contact with the channel layer, and extending between the source and the drain;
a gate formed in contact with, and covering at least a portion of, the barrier layer, the gate having a first gate edge portion, a second gate edge portion, and a gate central portion;
a gate electrode contacting the gate central portion;
a first gate field plate contacting a first side of the gate electrode;
a second gate field plate contacting a second side of the gate electrode;
a first dielectric layer formed between the first gate edge portion and the first gate field plate; and
a second dielectric layer formed between the second gate edge portion and the second gate field plate.

2. The HEMT of claim 1, wherein the gate has a gate length that extends from a first end of the first gate edge portion to a second end of the second gate edge portion, and wherein the first gate field plate extends from the gate electrode to at least the first end, and the second gate field plate extends from the gate electrode to at least the second end.

3. The HEMT of claim 2, wherein the first gate field plate extends past the first end, and the second gate field plate extends past the second end.

4. The HEMT of claim 3, wherein the gate electrode further includes a first perpendicular field plate extending from, and substantially perpendicular to, the first gate field plate, and a second perpendicular gate field plate extending from, and substantially perpendicular to, the second gate field plate.

5. The HEMT of claim 1, wherein the gate has a gate length that extends from a first end of the first gate edge portion to a second end of the second gate edge portion, and wherein the first gate field plate is recessed from the first end and the second gate field plate is recessed from the second end.

6. The HEMT of claim 1, further comprising a gate metal in electrical contact with the gate electrode, wherein the gate extends in a perpendicular direction that is substantially perpendicular to a line through the first gate edge portion, the second gate edge portion, and the gate central portion, and wherein the gate metal and the gate electrode extend in electrical contact with one another and with the gate along a portion of the gate in the perpendicular direction.

7. The HEMT of claim 6, further comprising a passivation dielectric formed over the gate electrode in the perpendicular direction when the gate metal extends in electrical contact with the gate electrode and with the gate over only the portion of the gate in the perpendicular direction.

8. The HEMT of claim 6, further comprising a passivation dielectric formed around the gate and the gate electrode, wherein the gate electrode extends through a portion of the passivation dielectric and the gate metal is formed on the gate electrode.

9. The HEMT of claim 1, wherein, during a biasing of the gate by a voltage applied at the gate electrode, the first gate field plate and the first gate edge portion are capacitively coupled through the first dielectric layer, and the second gate field plate and the second gate edge portion are capacitively coupled through the second dielectric layer.

10. A gate structure for a High Electron Mobility Transistor (HEMT) device, comprising:
a gate formed in contact with, and covering a portion of, a barrier layer of the HEMT, the gate having a first gate edge portion, a second gate edge portion, and a gate central portion;
a gate electrode formed in contact with the gate;
a first gate field plate contacting a first side of the gate electrode;
a second gate field plate contacting a second side of the gate electrode;
a first dielectric layer formed between the first gate edge portion and the first gate field plate; and
a second dielectric layer formed between the second gate edge portion and the second gate field plate.

11. The gate structure of claim 10, wherein the gate has a gate length that extends from a first end of the first gate edge portion to a second end of the second gate edge portion, and wherein the first gate field plate extends from the gate electrode to at least the first end, and the second gate field plate extends from the gate electrode to at least the second end.

12. The gate structure of claim 11, wherein the first gate field plate extends past the first end, and the second gate field plate extends past the second end.

13. The gate structure of claim 12, wherein the gate electrode is further in contact with a first perpendicular gate field plate extending from, and substantially perpendicular to, the first gate field plate, and a second perpendicular gate field plate extending from, and substantially perpendicular to, the second gate field plate.

14. The gate structure of claim 10, wherein the gate has a gate length that extends from a first end of the first gate edge portion to a second end of the second gate edge portion, and wherein the first gate field plate is recessed from the first end and the second gate field plate is recessed from the second end.

15. A method of making a High Electron Mobility Transistor (HEMT), comprising:
forming a layer stack that includes at least a channel layer and a barrier layer adjacent to the channel layer and forming a heterojunction at which a current channel is defined in the channel layer;
forming a gate having a first gate edge portion, a second gate edge portion, and a gate central portion;
forming a gate electrode contacting the gate central portion;
forming a first gate field plate contacting a first side of the gate electrode;
forming a second gate field plate contacting a second side of the gate electrode;
forming a first dielectric layer between the first gate edge portion and the first gate field plate; and
forming a second dielectric layer between the second gate edge portion and the second gate field plate.

16. The method of claim 15, wherein the first gate field plate, the second gate field plate, the first dielectric layer, and the second dielectric layer are formed in a self-aligned manner.

17. The method of claim 15, comprising:
forming a dielectric layer over the gate;
forming a gate field plate layer over the dielectric layer;
etching through the gate field plate layer and the dielectric layer to reach the gate, thereby separating the dielectric layer into the first dielectric layer and the second dielectric layer, and separating the gate field plate layer into the first gate field plate and the second gate field plate; and
forming the gate electrode between the first gate field plate and the second gate field plate, and in electrical contact with the gate central portion.

18. The method of claim 15, comprising:
forming the gate with a gate length that extends from a first end of the first gate edge portion to a second end of the second gate edge portion; and
forming the gate electrode with the first gate field plate extending from the gate electrode to at least the first end, and the second gate field plate extending from the gate electrode to at least the second end.

19. The method of claim 18, wherein the first gate field plate extends past the first end, and the second gate field plate extends past the second end.

20. The method of claim 15, comprising:
forming the gate with a gate length that extends from a first end of the first gate edge portion to a second end of the second gate edge portion; and
forming the first gate field plate being recessed from the first end and the second gate field plate being recessed from the second end.
